(19) United States
(12) Patent Application Publication
(10) Pub. No.: US 2019/0267570 A1
(43) Pub. Date: Aug. 29, 2019

(54) OLED DISPLAY DEVICE

(71) Applicant: Wuhan China Star Optoelectronics Semiconductor Display Technology Co., Ltd., Wuhan (CN)

(72) Inventors: Jing HUANG, Wuhan (CN); Hsianglun HSU, Wuhan (CN)

(21) Appl. No.: 16/152,145

(22) Filed: Oct. 4, 2018

Related U.S. Application Data
(63) Continuation of application No. PCT/CN2018/080854, filed on Mar. 28, 2018.

(30) Foreign Application Priority Data
Feb. 27, 2018 (CN) 201810162851.4

(51) Int. Cl. H01L 51/52; H01L 27/32

(52) U.S. Cl. CPC H01L 51/5253; H01L 51/0097; H01L 27/3258; H01L 27/3246

(57) ABSTRACT

An OLED display device is disclosed. The device includes: a base substrate; a planarization layer disposed on the substrate, an outer barrier wall, and an inner barrier wall; multiple light emitting devices and a pixel defining layer disposed on the planarization layer; a first inorganic layer covering the pixel defining layer and each light emitting device, wherein the first inorganic layer is extended to the inner barrier wall and covering the inner barrier wall; an organic layer disposed on the first inorganic layer, and an extending length of the organic layer is less than an extending length of the first inorganic layer; and a second inorganic layer disposed on the organic layer, the first inorganic layer, the outer barrier wall and the base substrate; wherein, the second inorganic layer is in a discontinuous connection state using the outer barrier wall as a breakpoint.

### CROSS REFERENCE

This application is a continuing application of PCT Patent Application No. PCT/CN2018/080854, entitled “OLED DISPLAY DEVICE”, filed on Mar. 28, 2018, which claims priority to China Patent Application No. 201810162851.4, filed on Feb. 27, 2018, both of which are hereby incorporated in its entireties by reference.

### FIELD OF THE INVENTION

The present invention relates to a flexible display technology field, and more particularly to an OLED display device.

### BACKGROUND OF THE INVENTION

The Organic Light-Emitting Diode (OLED) has the advantages of fast response, wide temperature range, self-luminous, and flexible display, and is regarded as a third-generation display technology after CRT, LCD, and LED. With the continuous increasing in market demand, the development and production of flexible OLED has become a hot area for display industry. However, because the organic material is particularly sensitive to external water and oxygen, flexible encapsulating is directly related to the display lifetime of the OLED, which is also one of the bottlenecks that limit the development of OLED.

At present, a flexible encapsulating mainly adopts an inorganic/organic/inorganic laminated structure. It is required not only to fully block external water and oxygen erosion, but also to effectively cover particle contamination that cannot be avoided in the production process and buffer stress in bending and folding process. The organic layer in the encapsulation structure is generally realized by flash evaporation, inkjet printing (IJP), and the like, wherein the IJP method has a shorter encapsulating time and an excellent planarization effect, but the organic layer is coated with a monomer that has a relatively high fluidity such that the boundary of the organic layer cannot be well controlled. Accordingly, a barrier wall (dam) is usually adopted at periphery of the display region to block the flow of the organic layer.

In order to completely block the flow of the organic layer, at least two barrier walls will be fabricated. This requires that the outermost inorganic layer boundary when manufacturing the encapsulation structure should exceed at least the outermost edge of the barrier wall in order to ensure that water and oxygen will not quickly enter the edge. However, the design of the narrow frame is unfavorable, mainly because the outermost inorganic layer is prepared by using the entire surface coating to form a continuously connected film layer, so that the mechanical stress generated by the cutting during the production of the narrow frame will continue to be transmitted. The edge of the outermost inorganic layer cracks, which affects the surface roughness of the product.

### SUMMARY OF THE INVENTION

The technical problem to be solved in the embodiment of the present invention is to provide an OLED display device, which ensures that the outermost inorganic layer has discontinuity through the outer barrier wall to ensure that the mechanical stress generated by cutting is effectively interrupted, and can effectively prevent the film from breaking when cutting, and ensure the product surface roughness.

In order to solve the above technology problem, the embodiment of the present invention provides an OLED display device, comprising: a base substrate, a planarization layer disposed on the substrate, an outer barrier wall, and an inner barrier wall located between the planarization layer and the outer side wall; wherein the outer barrier wall is provided with a first side surface facing toward the planarization layer and a second side surface away from the planarization layer, and at least one of the first side surface and the second side surface forms an acute angle relationship with the base substrate; multiple light emitting devices and a pixel defining layer disposed on the planarization layer, wherein each light emitting device is received in a corresponding groove formed on the pixel defining layer; a first inorganic layer covering the pixel defining layer and each light emitting device, wherein the first inorganic layer is extended to the inner barrier wall and covering the inner barrier wall; an organic layer disposed on the first inorganic layer, and the organic layer is extended between the inner barrier wall and the pixel defining layer, and an extending length of the organic layer is less than an extending length of the first inorganic layer; and a second inorganic layer disposed on the organic layer, the first inorganic layer, the outer barrier wall and the base substrate; wherein, the second inorganic layer is in a discontinuous connection state using the outer barrier wall as a breakpoint because at least one of the first side surface and the second side surface in the outer barrier wall forms an acute angle relationship with the base substrate.

Wherein the outer barrier wall is an inverted trapezoidal column body, and each of the first side surface and the second side surface of the outer barrier wall forms an acute angle less than or equal to 45 degrees with the base substrate.

Wherein a height of the outside barrier wall 25 is in a range of 0.01 um˜3 um, and a width of the outside barrier wall 25 is in a range of between 5 um˜50 um

Wherein the inner barrier wall and the outer barrier wall have a same structure.

Wherein a material of each of the inner barrier wall and the outer barrier wall includes epoxy resin, polyimide and poly(methyl methacrylate).

Wherein a thickness of the organic layer is in a range of 4 μm˜10 μm, and a material of the organic layer includes acrylate, hexamethyldisiloxane, polyacrylates, polycarbonate and polystyrene.

Wherein a thickness of each of the first inorganic layer and the second inorganic layer is in a range of 0.1 μm˜2 μm, and a material of each of the first inorganic layer and the second inorganic layer include epoxy resin, polyimide, and polymethyl methacrylate.

Wherein each light emitting device includes an anode and an organic light emitting layer disposed on the anode.

Wherein the organic light emitting layer includes a hole injecting layer, a hole transporting layer, a light emitting layer, an electron transporting layer, an electron injecting layer, a cathode and an optical path adjusting layer on the cathode.

Wherein the base substrate is a TFT array substrate.

Correspondingly, the embodiment of the present invention also provides another OLED display device, comprising: a base substrate; a planarization layer disposed on the substrate, an outer barrier wall, and an inner barrier wall located between the planarization layer and the outer side wall; wherein the outer barrier wall is provided with a first side surface facing toward the planarization layer and a second side surface away from the planarization layer, and at least one of the first side surface and the second side surface forms an acute angle relationship with the base substrate; multiple light emitting devices and a pixel defining layer disposed on the planarization layer, wherein each light emitting device is received in a corresponding groove formed on the pixel defining layer; a first inorganic layer covering the pixel defining layer and each light emitting device, wherein the first inorganic layer is extended to the inner barrier wall and covering the inner barrier wall; an organic layer disposed on the first inorganic layer, and the organic layer is extended between the inner barrier wall and the pixel defining layer, and an extending length of the organic layer is less than an extending length of the first inorganic layer; a second inorganic layer disposed on the organic layer, the first inorganic layer, the outer barrier wall and the base substrate; wherein, the second inorganic layer is in a discontinuous connection state using the outer barrier wall as a breakpoint because at least one of the first side surface and the second side surface in the outer barrier wall forms an acute angle relationship with the base substrate; wherein the outer barrier wall is an inverted trapezoidal column body, and each of the first side surface and the second side surface of the outer barrier wall forms an acute angle less than or equal to 45 degrees with the base substrate; and wherein the inner barrier wall and the outer barrier wall have a same structure.

Wherein a material of each of the inner barrier wall and the outer barrier wall includes epoxy resin, polyimide and poly(methyl methacrylate).

Wherein a thickness of the organic layer is in a range of 4 μm˜10 μm, and a material of the organic layer includes acrylate, hexamethyldisiloxane, polyacrylates, polycarbonate and polystyrene.

Wherein a thickness of each of the first inorganic layer and the second inorganic layer is in a range of 0.1 μm˜2 μm, and a material of each of the first inorganic layer and the second inorganic layer include epoxy resin, polyimide, and polymethyl methacrylate.

Wherein each light emitting device includes an anode and an organic light emitting layer disposed on the anode.

Wherein the organic light emitting layer includes a hole injecting layer, a hole transporting layer, a light emitting layer, an electron transporting layer, an electron injecting layer, a cathode and an optical path adjusting layer on the cathode.

Wherein the base substrate is a TFT array substrate.

Correspondingly, the embodiment of the present invention also provides another OLED display device, comprising: a base substrate; a planarization layer disposed on the substrate, an outer barrier wall, and an inner barrier wall located between the planarization layer and the outer side wall; wherein the outer barrier wall is provided with a first side surface facing toward the planarization layer and a second side surface away from the planarization layer, and at least one of the first side surface and the second side surface forms an acute angle relationship with the base substrate; multiple light emitting devices and a pixel defining layer disposed on the planarization layer, wherein each light emitting device is received in a corresponding groove formed on the pixel defining layer; a first inorganic layer covering the pixel defining layer and each light emitting device, wherein the first inorganic layer is extended to the inner barrier wall and covering the inner barrier wall; an organic layer disposed on the first inorganic layer, and the organic layer is extended between the inner barrier wall and the pixel defining layer, and an extending length of the organic layer is less than an extending length of the first inorganic layer; a second inorganic layer disposed on the organic layer, the first inorganic layer, the outer barrier wall and the base substrate; wherein, the second inorganic layer is in a discontinuous connection state using the outer barrier wall as a breakpoint because at least one of the first side surface and the second side surface in the outer barrier wall forms an acute angle relationship with the base substrate; wherein a height of the outside barrier wall 25 is in a range of 0.01 um˜3 um, and a width of the outside barrier wall 25 is in a range of between 5 um˜50 um; wherein an inner barrier wall and an outer barrier wall have a same structure; and wherein a material of each of the inner barrier wall and the outer barrier wall includes epoxy resin, polyimide and poly(methyl methacrylate).

Wherein a thickness of the organic layer is in a range of 4 μm˜10 μm, and a material of the organic layer includes acrylate, hexamethyldisiloxane, polyacrylates, polycarbonate and polystyrene.

Wherein a thickness of each of the first inorganic layer and the second inorganic layer is in a range of 0.1 μm˜2 μm, and a material of each of the first inorganic layer and the second inorganic layer include epoxy resin, polyimide, and polymethyl methacrylate.

The embodiment of the present invention has the following beneficial effects: in the present invention, through the outer barrier wall the outermost inorganic layer (that is a second inorganic layer) has discontinuity to ensure that the mechanical stress generated by cutting is effectively interrupted, and can effectively prevent the film from breaking when cutting, and ensure the product surface roughness, which facilitates the development of narrow frame design.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a schematic structural sectional view of an OLED display device according to an embodiment of the present invention, and

FIG. 2 is a schematic partial plan view of an angle formed between the outer barrier wall and the base substrate in FIG. 1.

### DETAILED DESCRIPTION OF THE PREFERRED EMBODIMENT

Through following to combine figures to describe in detail, the above, the other purposes, the features and benefits of the exemplary embodiment of the present disclosure will become clearer.

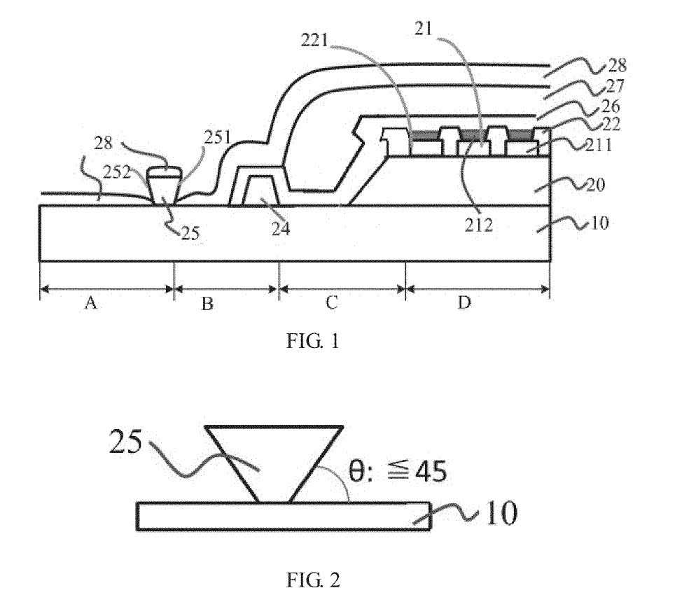

As shown in FIG. 1, an OLED display device provided in a first embodiment of the present invention includes:

a base substrate 10;

a planarization layer 20 disposed on the substrate 10, an outer barrier wall 25, and an inner barrier wall 24 located between the planarization layer 20 and the outer side wall 25; wherein the outer barrier wall 25 is provided with a first side surface 251 facing toward the planarization layer 20 and a second side surface 252 away from the planarization layer 20, and at least one of the first side surface 251 and the second side surface 252 forms an acute angle relationship with the base substrate 10;

multiple light emitting devices 21 and a pixel defining layer 22 disposed on the planarization layer 20, wherein each light emitting device 21 is received in a corresponding groove 221 formed on the pixel defining layer 22;

a first inorganic layer 26 covering the pixel defining layer 22 and each light emitting device 21, wherein the first inorganic layer 26 is extended to the inner barrier wall 24 and covering the inner barrier wall 24;

an organic layer 27 disposed on the first inorganic layer 26, and the organic layer 27 is extended between the inner barrier wall 24 and the pixel defining layer 22, and an extending length of the organic layer 27 is less than an extending length of the first inorganic layer 26;

a second inorganic layer 28 disposed on the organic layer 27, the first inorganic layer 26, the outer barrier wall 25 and the base substrate 10; wherein, the second inorganic layer 28 is in a discontinuous connection state using the outer barrier wall 25 as a breakpoint because at least one of the first side surface 251 and the second side surface 252 in the outer barrier wall 25 forms an acute angle relationship with the base substrate 10.

It can be understood that, in the OLED device of FIG. 1, using the light emitting device 21, the inner barrier wall 24, and the outer barrier wall 25 as demarcation points, four regions are generated, respectively, a display region D, a first region C corresponding to the inner barrier wall 24 to the display area D, a second encapsulation region B corresponding to the outer barrier wall 25 to the inner barrier wall 24, and a third encapsulation region A corresponding to an edge of the substrate 10 away from the display area D to the outer barrier wall 25. At this time, the light emitting device 21 is provided in the display area D, the organic layer 27 is limited to the first encapsulation region C, and the second inorganic layer 28 is segmented in the second encapsulation region B and the third encapsulation region A. Therefore, when the narrow frame is manufactured, the mechanical stress generated when cutting the third encapsulation area A is interrupted at the outer barrier wall 25 such that at most, a crack may generated at the second inorganic layer 28 located at the third encapsulation region A in order to ensure that the second encapsulation region B, the first encapsulation region C, and the display region D are undamaged and complete, which is favorable for the development and design of the narrow frame products.

It should be noted that the second inorganic layer 28 is directly coated with an entire surface coating method without using a mask plate, which is beneficial to the effectiveness of the product surface roughness and the development of the narrow frame OLED, and can be generally applied to flexible, folded, and curled OLED.

In the first embodiment of the present invention, the outer barrier wall 25 has a variety of structures, including an inverted trapezoidal column body, an ellipsoid, etc., which only need to satisfy that at least one of the first side surface 251 and the second side surface 252 forms an acute angle less than or equal to 45 degrees with the base substrate 10. In an embodiment, as shown in FIG. 2, the outer barrier wall 25 is an inverted trapezoidal column, each of a side of the outer barrier wall 25 facing toward the planarization layer 20 (that is, the first side surface 251) and a side of the outer barrier wall 25 away from the planarization layer 20 (that is, the second side surface 252) forms an acute angle less than or equal to 45 degrees with the base substrate 10.

In order to meet the process requirements, a height of the outside barrier wall 25 is in a range of 0.01 um˜3 um, and a width of the outside barrier wall 25 is in a range of between 5 um˜50 um.

Of course, in order to further interrupt the transmission of the cutting stress, the inner barrier wall 24 and the outer barrier wall 25 have the same structure, that is, the inner barrier wall 24 forms a third side surface facing toward the planarization layer 20 and a fourth side surface away from the planarization layer 20. At least one of the third side surface and the fourth side surface of the inner barrier wall 24 forms an acute angle less than or equal to 45 degrees with the base substrate 10 so as to interrupt the transmission of the cutting stress at the inner barrier wall 24 and prevent a risk of film break of the second inorganic layer 28 by the mechanical stress when cutting, and prevent a risk of film break of the first inorganic layer 26 by the mechanical stress when cutting.

In the first embodiment of the present invention, the material used for the inner barrier wall 24 and the outer barrier wall 25 includes epoxy resin, polyimide and poly(methyl methacrylate).

In the first embodiment of the present invention, a thickness of the organic layer 27 is in a range of 4 μm˜10 μm, and the materials include acrylate, hexamethyldisiloxane, polyacrylates, polycarbonate and polystyrene, and is manufactured through an ink jet printing, plasma enhanced chemical vapor deposition, or the like. The thickness of each of the first inorganic layer 26 and the second inorganic layer 28 is in a range of 0.1 μm˜2 μm, and the materials include epoxy resin, polyimide, and polymethyl methacrylate, and manufactured through plasma enhanced chemical vapor deposition, atomic layer deposition or physical vapor deposition.

In an embodiment of the present invention, each light emitting device includes an anode 211 and an organic light emitting layer 212 disposed on the anode 211, and the organic light emitting layer 212 includes a hole injecting layer, a hole transporting layer, a light emitting layer, an electron transporting layer, an electron injecting layer, a cathode and an optical path adjusting layer on the cathode.

In an embodiment of the present invention, the base substrate 10 is a TFT array substrate. The base substrate 10 may be a TFT array substrate, including a base and a driving circuit thereon.

In summary, the embodiment of the present invention has the following beneficial effects: in the present invention, through the outer barrier wall the outermost inorganic layer (that is a second inorganic layer) has discontinuity to ensure that the mechanical stress generated by cutting is effectively interrupted, and can effectively prevent the film from breaking when cutting, and ensure the product surface roughness, which facilitates the development of narrow frame design.

The above is only the specific implementation mode of the present disclosure and not intended to limit the scope of protection of the present disclosure, and any variations or replacements apparent to those skilled in the art within the technical scope of the present disclosure shall fall within the scope of protection of the present disclosure. Therefore, the scope of protection of the present disclosure should be the scope of protection of the claims.

What is claimed is:

1. An OLED display device, comprising:
a base substrate;
a planarization layer disposed on the substrate, an outer barrier wall, and an inner barrier wall located between the planarization layer and the outer side wall; wherein the outer barrier wall is provided with a first side surface facing toward the planarization layer and a second side surface away from the planarization layer, and at least one of the first side surface and the second side surface forms an acute angle relationship with the base substrate;
multiple light emitting devices and a pixel defining layer disposed on the planarization layer, wherein each light emitting device is received in a corresponding groove formed on the pixel defining layer;
a first inorganic layer covering the pixel defining layer and each light emitting device, wherein the first inorganic layer is extended to the inner barrier wall and covering the inner barrier wall;
an organic layer disposed on the first inorganic layer, and the organic layer is extended between the inner barrier wall and the pixel defining layer, and an extending length of the organic layer is less than an extending length of the first inorganic layer; and
a second inorganic layer disposed on the organic layer, the first inorganic layer, the outer barrier wall and the base substrate; wherein, the second inorganic layer is in a discontinuous connection state using the outer barrier wall as a breakpoint because at least one of the first side surface and the second side surface in the outer barrier wall forms an acute angle relationship with the base substrate.

2. The OLED display device according to claim 1, wherein the outer barrier wall is an inverted trapezoidal column body, and each of the first side surface and the second side surface of the outer barrier wall forms an acute angle less than or equal to 45 degrees with the base substrate.

3. The OLED display device according to claim 2, wherein a height of the outside barrier wall 25 is in a range of 0.01 um˜3 um, and a width of the outside barrier wall 25 is in a range of between 5 um˜50 um.

4. The OLED display device according to claim 3, wherein the inner barrier wall and the outer barrier wall have a same structure.

5. The OLED display device according to claim 4, wherein a material of each of the inner barrier wall and the outer barrier wall includes epoxy resin, polyimide and poly(methyl methacrylate).

6. The OLED display device according to claim 5, wherein a thickness of the organic layer is in a range of 4 μm˜10 μm, and a material of the organic layer includes acrylate, hexamethyldisiloxane, polyacrylates, polycarbonate and polystyrene.

7. The OLED display device according to claim 6, wherein a thickness of each of the first inorganic layer and the second inorganic layer is in a range of 0.1 μm˜2 μm, and a material of each of the first inorganic layer and the second inorganic layer include epoxy resin, polyimide, and polymethyl methacrylate.

8. The OLED display device according to claim 7, wherein each light emitting device includes an anode and an organic light emitting layer disposed on the anode.

9. The OLED display device according to claim 8, wherein the organic light emitting layer includes a hole injecting layer, a hole transporting layer, a light emitting layer, an electron transporting layer, an electron injecting layer, a cathode and an optical path adjusting layer on the cathode.

10. The OLED display device according to claim 9, wherein the base substrate is a TFT array substrate.

11. An OLED display device, comprising:
a base substrate;
a planarization layer disposed on the substrate, an outer barrier wall, and an inner barrier wall located between the planarization layer and the outer side wall; wherein the outer barrier wall is provided with a first side surface facing toward the planarization layer and a second side surface away from the planarization layer, and at least one of the first side surface and the second side surface forms an acute angle relationship with the base substrate;
multiple light emitting devices and a pixel defining layer disposed on the planarization layer, wherein each light emitting device is received in a corresponding groove formed on the pixel defining layer;
a first inorganic layer covering the pixel defining layer and each light emitting device, wherein the first inorganic layer is extended to the inner barrier wall and covering the inner barrier wall;
an organic layer disposed on the first inorganic layer, and the organic layer is extended between the inner barrier wall and the pixel defining layer, and an extending length of the organic layer is less than an extending length of the first inorganic layer;
a second inorganic layer disposed on the organic layer, the first inorganic layer, the outer barrier wall and the base substrate; wherein, the second inorganic layer is in a discontinuous connection state using the outer barrier wall as a breakpoint because at least one of the first side surface and the second side surface in the outer barrier wall forms an acute angle relationship with the base substrate;
wherein the outer barrier wall is an inverted trapezoidal column body, and each of the first side surface and the second side surface of the outer barrier wall forms an acute angle less than or equal to 45 degrees with the base substrate; and
wherein the inner barrier wall and the outer barrier wall have a same structure.

12. The OLED display device according to claim 11, wherein a material of each of the inner barrier wall and the outer barrier wall includes epoxy resin, polyimide and poly(methyl methacrylate).

13. The OLED display device according to claim 12, wherein a thickness of the organic layer is in a range of 4 μm˜10 μm, and a material of the organic layer includes acrylate, hexamethyldisiloxane, polyacrylates, polycarbonate and polystyrene.

14. The OLED display device according to claim 13, wherein a thickness of each of the first inorganic layer and the second inorganic layer is in a range of 0.1 μm˜2 μm, and a material of each of the first inorganic layer and the second inorganic layer include epoxy resin, polyimide, and polymethyl methacrylate.

15. The OLED display device according to claim 14, wherein each light emitting device includes an anode and an organic light emitting layer disposed on the anode.

16. The OLED display device according to claim 15, wherein the organic light emitting layer includes a hole injecting layer, a hole transporting layer, a light emitting layer, an electron transporting layer, an electron injecting layer, a cathode and an optical path adjusting layer on the cathode.

17. The OLED display device according to claim 16, wherein the base substrate is a TFT array substrate.

18. An OLED display device, comprising:
a base substrate;
a planarization layer disposed on the substrate, an outer barrier wall, and an inner barrier wall located between the planarization layer and the outer side wall; wherein the outer barrier wall is provided with a first side surface facing toward the planarization layer and a second side surface away from the planarization layer, and at least one of the first side surface and the second side surface forms an acute angle relationship with the base substrate;
multiple light emitting devices and a pixel defining layer disposed on the planarization layer, wherein each light emitting device is received in a corresponding groove formed on the pixel defining layer;
a first inorganic layer covering the pixel defining layer and each light emitting device, wherein the first inorganic layer is extended to the inner barrier wall and covering the inner barrier wall;
an organic layer disposed on the first inorganic layer, and the organic layer is extended between the inner barrier wall and the pixel defining layer, and an extending length of the organic layer is less than an extending length of the first inorganic layer;
a second inorganic layer disposed on the organic layer, the first inorganic layer, the outer barrier wall and the base substrate; wherein, the second inorganic layer is in a discontinuous connection state using the outer barrier wall as a breakpoint because at least one of the first side surface and the second side surface in the outer barrier wall forms an acute angle relationship with the base substrate;
wherein a height of the outside barrier wall 25 is in a range of 0.01 um˜3 um, and a width of the outside barrier wall 25 is in a range of between 5 um˜50 um;
wherein an inner barrier wall and an outer barrier wall have a same structure; and
wherein a material of each of the inner barrier wall and the outer barrier wall includes epoxy resin, polyimide and poly(methyl methacrylate).

19. The OLED display device according to claim 18, wherein a thickness of the organic layer is in a range of 4 μm˜10 μm, and a material of the organic layer includes acrylate, hexamethyldisiloxane, polyacrylates, polycarbonate and polystyrene.

20. The OLED display device according to claim 19, wherein a thickness of each of the first inorganic layer and the second inorganic layer is in a range of 0.1 μm˜2 μm, and a material of each of the first inorganic layer and the second inorganic layer include epoxy resin, polyimide, and polymethyl methacrylate.
